(19) United States
(12) Patent Application Publication
(10) Pub. No.: US 2021/0384340 A1
(43) Pub. Date: Dec. 9, 2021

(54) SEMICONDUCTOR DEVICE AND MANUFACTURING METHOD

(71) Applicant: FUJITSU LIMITED, Kawasaki-shi (JP)

(72) Inventors: Shirou Ozaki, Yamato (JP); Kozo Makiyama, Kawasaki (JP); Toshihiro Ohki, Hadano (JP)

(73) Assignee: FUJITSU LIMITED, Kawasaki-shi (JP)

(21) Appl. No.: 17/190,255

(22) Filed: Mar. 2, 2021

(30) Foreign Application Priority Data
Jun. 5, 2020 (JP) 2020-098696

(51) Int. Cl. H01L 29/778; H01L 29/20; H01L 29/417; H01L 29/40; H01L 29/66

(52) U.S. Cl. CPC H01L 29/7786; H01L 29/2003; H01L 29/66462; H01L 29/401; H01L 29/41775

(57) ABSTRACT

A disclosed semiconductor device includes a semiconductor stack structure having an electron transit layer and an electron supply layer, the electron transit layer and the electron supply layer being compound semiconductors; a gate electrode, a source electrode, and a drain electrode, the gate electrode, the source electrode, and the drain electrode being deposed above the electron supply layer; a first insulating film disposed on the semiconductor stack structure between the gate electrode and the source electrode, the first insulating film being positively charged and in direct contact with the semiconductor stack structure; and a second insulating film disposed on the semiconductor stack structure between the gate electrode and the drain electrode, the second insulating film being covalent and in direct contact with the semiconductor stack structure.

### CROSS-REFERENCE TO RELATED APPLICATIONS

The present application is based upon and claims the benefit of priority from the prior Japanese Patent Application No. 2020-098696 filed on Jun. 5, 2020, with the Japanese Patent Office, the entire contents of which are incorporated herein by reference.

### FIELD

The disclosure discussed herein relates to a semiconductor device and a method for manufacturing the semiconductor device.

### BACKGROUND

Nitride semiconductors have features such as high saturated electron velocities and wide band gaps. Therefore, various studies have been conducted to apply nitride semiconductors to high-breakdown voltage and high-power semiconductor devices using these properties. Recently, techniques associated with GaN-based high electron mobility transistors (HEMTs) have been developed, for example.

According to one example of a GaN-based HEMT, GaN (gallium nitride) is used in an electron transit layer and AlGaN (aluminum gallium nitride) is used in an electron supply layer. In the electron transit layer, a high concentration of a two-dimensional electron gas (2DEG) is generated by the action of piezo polarization and spontaneous polarization in GaN. Hence, the application of GaN-based HEMTs to high-power amplifiers or high-efficiency switching devices is expected.

In the GaN-based HEMTs, it is preferable that the concentration of 2DEG differ between the source and drain electrodes. For example, to achieve both the reduction in on-resistance and the improvement in drain breakdown voltage, it is preferable to have a higher concentration of 2DEG between the gate and source electrodes than between the gate and drain electrodes.

### RELATED-ART DOCUMENTS

### Patent Document

[Patent Document 1] Japanese Patent Application Laid-Open No. 2015-12037

[Patent Document 2] Japanese Patent Application Laid-Open No. 2004-221325

[Patent Document 3] Japanese Patent Application Laid-Open No. 2012-114242

### SUMMARY

According to an aspect of the present disclosure, a semiconductor device is provided. The semiconductor device includes a semiconductor stack structure having an electron transit layer and an electron supply layer, the electron transit layer and the electron supply layer being compound semiconductors; a gate electrode, a source electrode, and a drain electrode, the gate electrode, the source electrode, and the drain electrode being deposed above the electron supply layer; a first insulating film disposed on the semiconductor stack structure between the gate electrode and the source electrode, the first insulating film being positively charged and in direct contact with the semiconductor stack structure; and a second insulating film disposed on the semiconductor stack structure between the gate electrode and the drain electrode, the second insulating film being covalent and in direct contact with the semiconductor stack structure.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating a semiconductor device according to a first embodiment;

FIG. 2 is a cross-sectional view (Part 1) illustrating a method for manufacturing the semiconductor device according to the first embodiment;

FIG. 3 is a cross-sectional view (Part 2) illustrating the method for manufacturing the semiconductor device according to the first embodiment;

FIG. 4 is a cross-sectional view (Part 3) illustrating the method for manufacturing the semiconductor device according to the first embodiment.

FIG. 5 is a cross-sectional view (Part 4) illustrating the method for manufacturing the semiconductor device according to the first embodiment;

FIG. 6 is a cross-sectional view illustrating a semiconductor device according to a second embodiment;

FIG. 7 is a cross-sectional view (Part 1) illustrating a method for manufacturing the semiconductor device according to the second embodiment;

FIG. 8 is a cross-sectional view (Part 2) illustrating the method for manufacturing the semiconductor device according to the second embodiment;

FIG. 9 is a cross-sectional view (Part 3) illustrating the method for manufacturing the semiconductor device according to the second embodiment;

FIG. 10 is a cross-sectional view (Part 4) illustrating the method for manufacturing the semiconductor device according to the second embodiment;

FIG. 11 is a cross-sectional view (Part 5) illustrating the method for manufacturing the semiconductor device according to the second embodiment;

FIG. 12 is a cross-sectional view (Part 6) illustrating the method for manufacturing the semiconductor device according to the second embodiment;

FIG. 13 is a cross-sectional view illustrating a semiconductor device according to a third embodiment;

FIG. 14 is a cross-sectional view (Part 1) illustrating a method for manufacturing the semiconductor device according to the third embodiment;

FIG. 15 is a cross-sectional view (Part 2) illustrating the method for manufacturing the semiconductor device according to the third embodiment;

FIG. 16 is a cross-sectional view (Part 3) illustrating a method for manufacturing a semiconductor device according to a third embodiment;

FIG. 17 is a cross-sectional view illustrating a semiconductor device according to a fourth embodiment;

FIG. 18 is a cross-sectional view (Part 1) illustrating a method for manufacturing the semiconductor device according to the fourth embodiment;

FIG. 19 is a cross-sectional view (Part 2) illustrating the method for manufacturing the semiconductor device according to a fourth embodiment;

FIG. 20 is a cross-sectional view (Part 3) illustrating the method for manufacturing the semiconductor device according to the fourth embodiment;

FIG. 21 is a cross-sectional view illustrating a semiconductor device according to a fifth embodiment;

FIG. 22 is a cross-sectional view (Part 1) illustrating a method for manufacturing the semiconductor device according to the fifth embodiment;

FIG. 23 is a cross-sectional view (Part 2) illustrating the method for manufacturing the semiconductor device according to the fifth embodiment;

FIG. 24 is a graph illustrating measurement results of carrier density;

FIG. 25 is a graph illustrating a relationship between a heat treatment temperature and a N/Si ratio;

FIG. 26 is a graph illustrating a thermal desorption profile for N₂;

FIG. 27 is a view illustrating a discrete package according to a sixth embodiment;

FIG. 28 is a line diagram illustrating a PFC circuit according to a seventh embodiment;

FIG. 29 is a line diagram illustrating a power supply device according to an eighth embodiment; and

FIG. 30 is a line diagram illustrating an amplifier according to a ninth embodiment.

### DESCRIPTION OF EMBODIMENTS

In related art HEMT structures, it appears difficult to stably improve the drain breakdown voltage while reducing on-resistance.

Thus, an object of the present disclosure is to provide a semiconductor device capable of stably improving the drain breakdown voltage while reducing the on-resistance, and a method for manufacturing such a semiconductor device.

Hereinafter, embodiments of the present disclosure will be described in detail with reference to the accompanying drawings. In the present specification and the drawings, duplicated descriptions for components having substantially the same functional structures may be omitted by adding the same reference numerals.

### First Embodiment

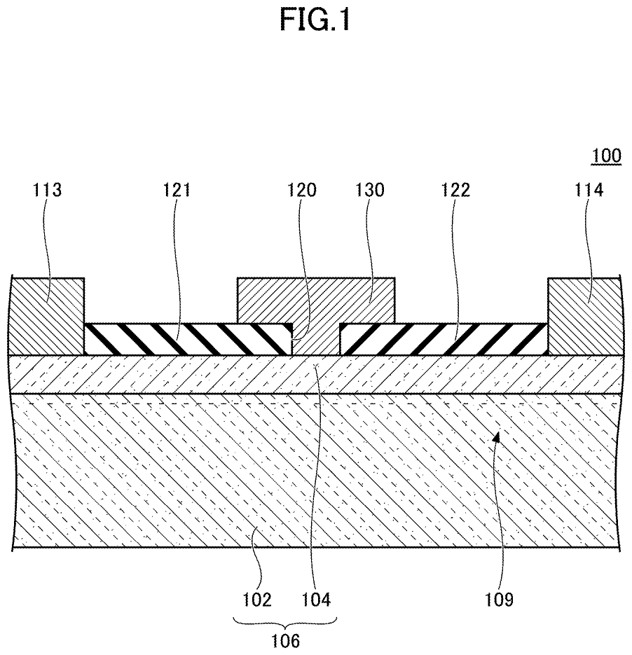

A first embodiment will be described. The first embodiment relates to a semiconductor device including a high electron mobility transistor (HEMT). FIG. 1 is a cross-sectional view illustrating a semiconductor device 100 according to the first embodiment.

The semiconductor device 100 according to a first embodiment has a semiconductor stack structure 106 that includes an electron transit layer 102 and an electron supply layer 104, as illustrated in FIG. 1. The electron transit layer 102 and the electron supply layer 104 are compound semiconductors. The semiconductor device 100 includes a gate electrode 130, a source electrode 113, and a drain electrode 114. The gate electrode 130, the source electrode 113, and the drain electrode 114 are disposed above the electron supply layer 104. The semiconductor device 100 includes a first positively charged ionic bonding insulating film 121 and a second covalent insulating film 122. The first insulating film 121 is disposed on the semiconductor stack structure 106 between the gate electrode 130 and the source electrode 113, and is in direct contact with semiconductor stack structure 106. The second insulating film 122 is disposed on the semiconductor stack structure 106 between the gate electrode 130 and the drain electrode 114, and is in direct contact with the semiconductor stack structure 106.

In the semiconductor device 100, a two-dimensional electron gas (2DEG) 109 is generated in the electron transit layer 102 near an interface with the electron supply layer 104. The first insulating film 121 is disposed on the semiconductor stack structure 106 between the gate electrode 130 and the source electrode 113, and is in direct contact with the semiconductor stack structure 106. The first insulating film 121 is positively charged. In contrast to this, the second insulating film 122 is disposed on the semiconductor stack structure 106 between the gate electrode 130 and the drain electrode 114, and is in direct contact with the semiconductor stack structure 106. The second insulating film 122 is a covalent insulating film. Covalent insulating films are electrically neutral because the covalent insulating films contain substantially no fixed charge. Thus, the concentration of 2DEG 109 is higher below the first insulating film 121 than below the second insulating film 122. Covalent insulating films are also thermally stable. Thus, the drain breakdown voltage can be stably improved while reducing the on-resistance and increasing the current.

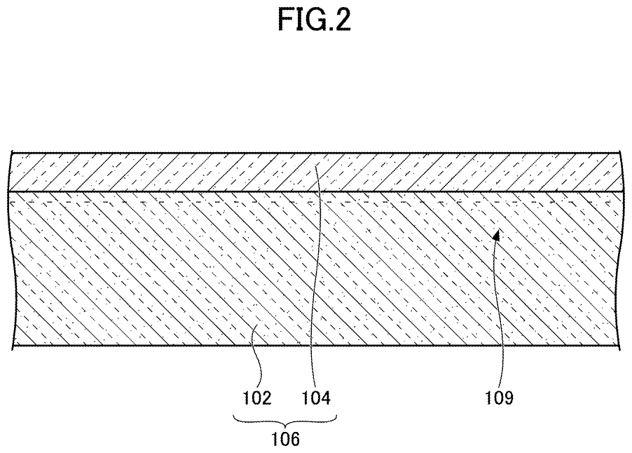

Next, a method for manufacturing the semiconductor device 100 according to the first embodiment will be described. FIGS. 2 to 5 are cross-sectional views illustrating a method for manufacturing the semiconductor device 100 according to the first embodiment.

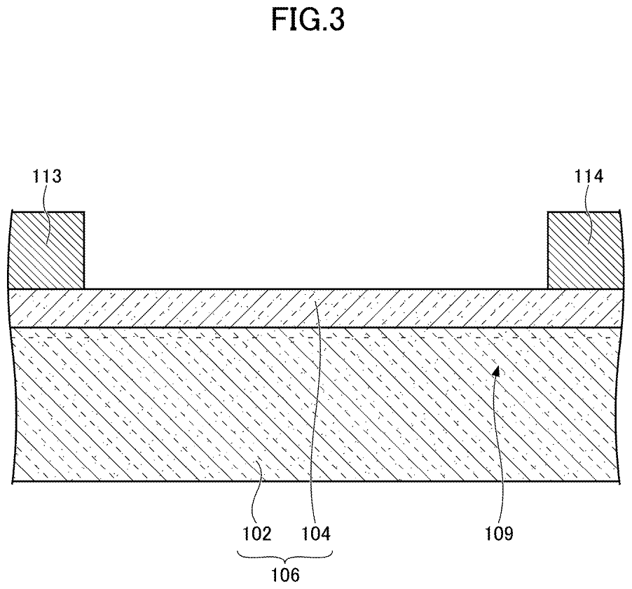

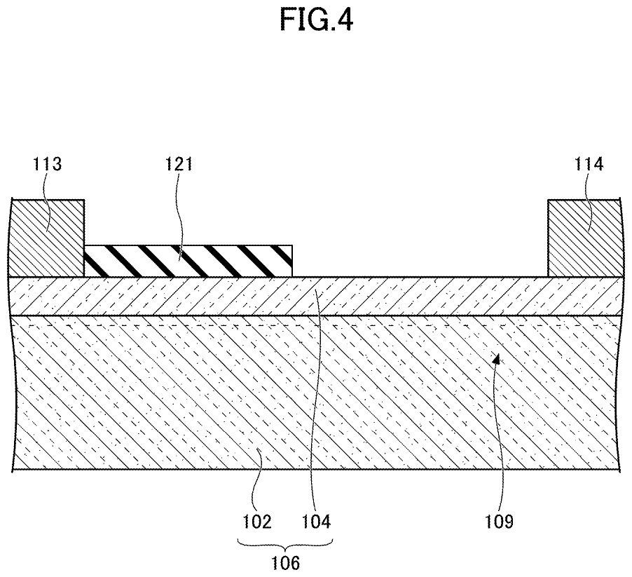

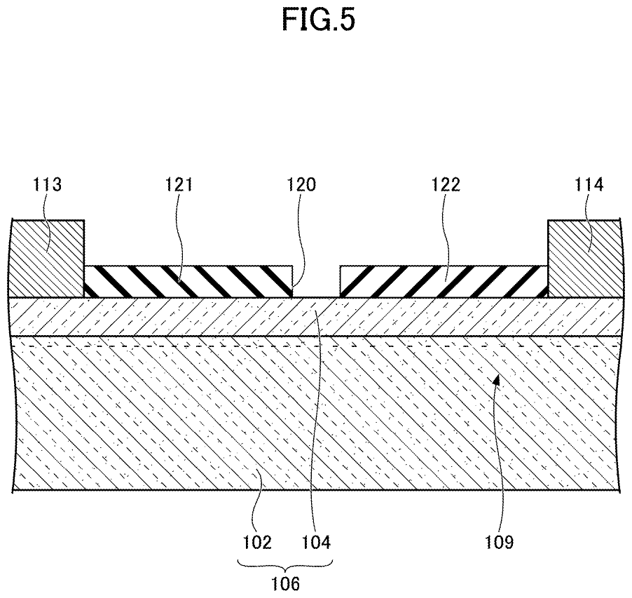

As illustrated in FIG. 2, a semiconductor stack structure 106 including an electron transit layer 102 and an electron supply layer 104 that are compound semiconductors is formed. A 2DEG 109 is formed near a surface of the electron transit layer 102. As illustrated in FIG. 3, a source electrode 113 and a drain electrode 114 are formed above the electron supply layer 104. As illustrated in FIG. 4, a first insulating film 121 is formed on the semiconductor stack structure 106 between the source electrode 113 and the drain electrode 114. The first insulating film 121 is separated from the drain electrode 114, and is in direct contact with the semiconductor stack structure 106. As illustrated in FIG. 5, a second insulating film 122 is formed on the semiconductor stack structure 106 between the source electrode 113 and the drain electrode 114. The second insulating film 122 is separated from the source electrode 113 and the first insulating film 121, and is in direct contact with the semiconductor stack structure 106. Then, the gate electrode 130 is formed between the first and second insulating films 121 and 122 above the electron supply layer 104 (see FIG. 1).

The semiconductor device 100 according to the first embodiment can be manufactured in this manner.

### Second Embodiment

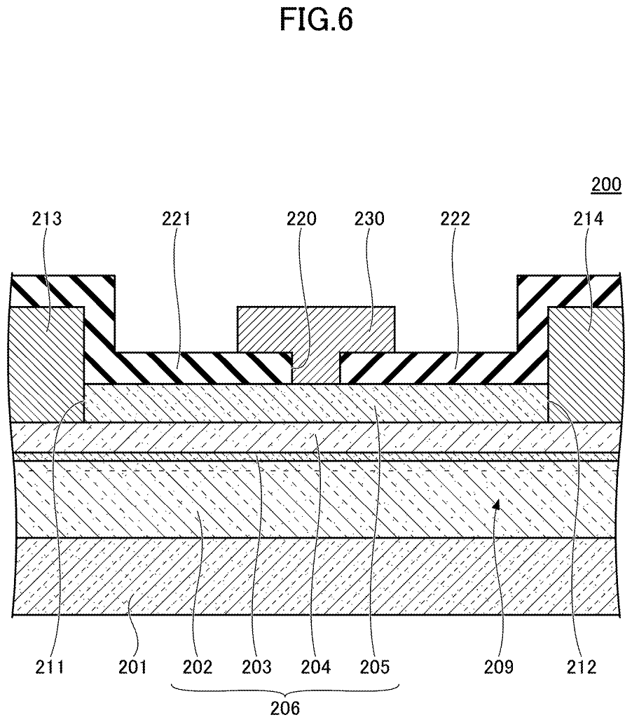

Next, a second embodiment will be described. The second embodiment relates to a semiconductor device having a GaN-based HEMT. FIG. 6 is a cross-sectional view illustrating a semiconductor device 200 according to the second embodiment.

The semiconductor device 200 according to the second embodiment has a semiconductor stack structure 206 formed on a substrate 201, as illustrated in FIG. 6. The semiconductor stack structure 206 includes, for example, an electron transit layer 202, a spacer layer 203, an electron supply layer 204, and a capping layer 205. The electron transit layer 202, the spacer layer 203, the electron supply layer 204, and the capping layer 205 are compound semiconductors. The substrate 201 is, for example, a silicon carbide (SiC) substrate. The electron transit layer 202 is a GaN layer (i-GaN layer) with a thickness of, for example, 2 μm to 4 μm and without intentional doping of impurities. The spacer layer 203 is an AlGaN layer (i-AlGaN layer) with a thickness of, for example, 4 nm to 6 nm and without intentional doping of impurities. The electron supply layer 204 is an n-type AlGaN layer (n-AlGaN layer) with a thickness of, for example, 25 nm to 35 nm. The capping layer 205 is, for example, a GaN layer with a thickness of, for example, 1 nm and 10 nm. The electron supply layer 204 is doped with a concentration of, for example, Si of approximately 5×10¹⁸ cm⁻³. The semiconductor stack structure 206 may include a buffer layer, such as AlGaN, between the electron transit layer 202 and the substrate 201.

Openings 211 and 212 are formed on the capping layer 205, the source electrode 213 is formed inside the opening 211, and the drain electrode 214 is formed inside the opening 212. The first insulating film 221 and the second insulating film 222 are formed on the capping layer 205. The first and second insulating films 221 and 222 are in direct contact with the semiconductor stack structure 206. The first insulating film 221 is in contact with the source electrode 213 and extends toward the drain electrode 214. An end of the first insulating film 221 toward the drain electrode 214 is separated from the drain electrode 214. The second insulating film 222 is in contact with the drain electrode 214 and extends toward the source electrode 213. An end of the second insulating film 222 toward the source electrode 213 is separated from the source electrode 213. The end of the first insulating film 221 facing the drain electrode 214 and the end of the second insulating film 222 facing the source electrode 213 are separated from each other, and an opening 220 is provided between these ends of the first and second insulating films 221 and 222. A gate electrode 230 is provided between the source electrode 213 and the drain electrode 214 on the first and second insulating films 221 and 222, and the gate electrode 230 is in contact with the capping layer 205 through the opening 220. The first insulating film 221 may cover the side and top surfaces of the source electrode 213, and the second insulating film 222 may cover the side and top surfaces of the drain electrode 214.

The source and drain electrodes 213 and 214 are made of, for example, metal, and may include a stack of a titanium (Ti) film and an aluminum (Al) film thereon. The gate electrode 230 has a so-called T-shaped structure. The gate electrode 230 is made of, for example, metal, and may include a stack of a nickel (Ni) film and a gold (Au) film thereon.

The first insulating film 221 includes aluminum oxide. The first insulating film 221 may, for example, be an aluminum oxide film. When the composition of aluminum oxide is expressed as Alₓ₁O_{y1}, the value of x1/y1 is greater than 2/3. The first insulating film 221 is a positively charged, ionic bonding film. The thickness of the first insulating film 221 may be, for example, 10 nm to 100 nm.

The second insulating film 222 is a covalent film. The second insulating film 222 may include, for example, siloxane polymers such as methylsilsesquioxane (MSQ). For example, the density of the second insulating film 222 is 1.1 g/cm³ or more, and the dielectric constant of the second insulating film 222 is 2.2 or more. The thickness of the second insulating film 222 may be, for example, 10 nm to 1000 nm.

In the semiconductor device 200, a 2DEG 209 is generated in the electron transit layer 202 near an interface with the electron supply layer 204. The first insulating film 221 is disposed on the semiconductor stack structure 206 between the gate electrode 230 and the source electrode 213, and is in direct contact with the semiconductor stack structure 206. The first insulating film 221 is positively charged. In contrast to this, the second insulating film 222 is disposed on the semiconductor stack structure 206 between the gate electrode 230 and the drain electrode 214, and is in direct contact with the semiconductor stack structure 206. The second insulating film 222 is a covalent insulating film. Covalent insulating films are electrically neutral because the covalent insulating films contain substantially no fixed charge. Thus, the concentration of the 2DEG 209 is higher below the first insulating film 221 than below the second insulating film 222. Covalent insulating films are thermally stable. Thus, the drain breakdown voltage can be stably improved while reducing the on-resistance and increasing the current.

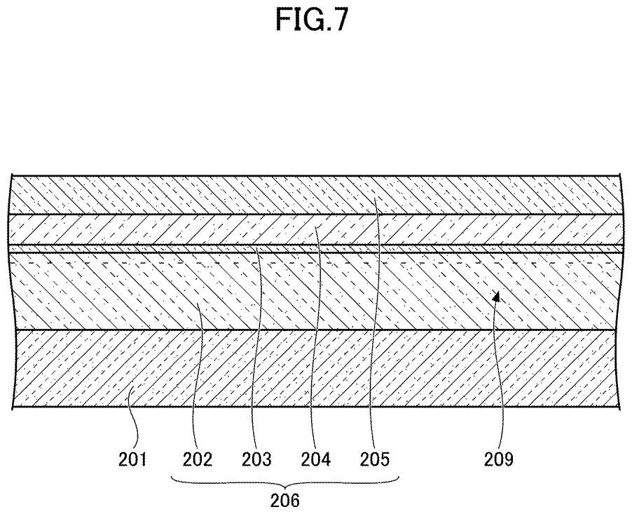

Next, a method for manufacturing the semiconductor device 200 according to the second embodiment will be described. FIGS. 7 to 12 are cross-sectional views illustrating a method for manufacturing the semiconductor device 200 according to the second embodiment.

First, as illustrated in FIG. 7, a semiconductor stack structure 206 is formed on the substrate 201. The semiconductor stack structure 206 includes an electron transit layer 202, a spacer layer 203, an electron supply layer 204, and a capping layer 205. The semiconductor stack structure 206 can be formed by, for example, metal-organic vapor phase epitaxy (MOVPE). As a result, 2DEG 209 is formed near a surface of the electron transit layer 202.

In forming the semiconductor stack structure 206, for example, a mixture of trimethylaluminum (TMAl) gas, which is an Al source, trimethylgallium (TMG) gas, which is a Ga source, and ammonia (NH₃) gas, which is an N source, is used. In this case, the presence or absence of the supply of trimethylaluminum gas and trimethylgallium gas and the flow rate thereof are set according to a composition of a compound semiconductor layer to be grown. The flow rate of the ammonia gas, which is a common precursor for each compound semiconductor layer, is approximately 100 ccm to 10 LM. For example, the growth pressure is approximately 50 Torr to 300 Torr, and the growth temperature is approximately 1000° C. to 1200° C. Also, when growing an n-type compound semiconductor layer (e.g., an electron supply layer 204), a SiH₄ gas containing, for example, Si is added to the mixture at a predetermined flow rate to dope the compound semiconductor layer with Si. The doping concentration of Si may be, for example, from approximately 1×10¹⁸ cm⁻³ to 1×10²⁰ cm⁻³.

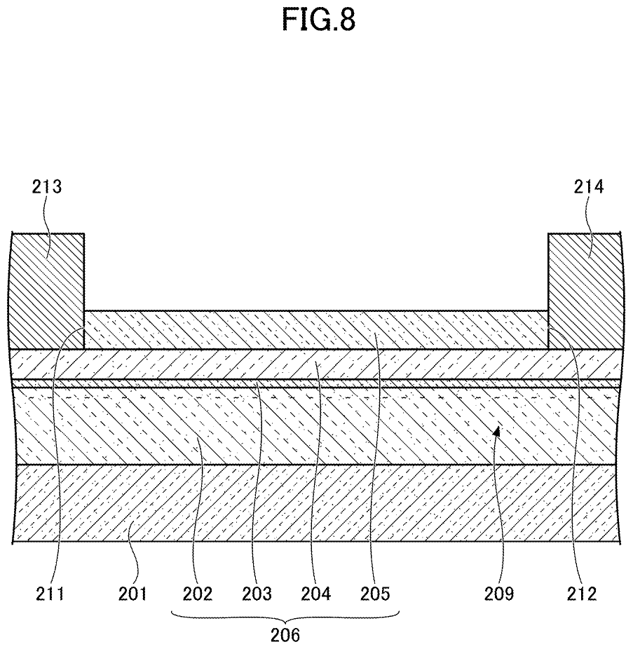

Subsequently, as illustrated in FIG. 8, openings 211 and 212 are formed on the capping layer 205, a source electrode 213 is formed in the opening 211, and a drain electrode 214 is formed in the opening 212. For example, a resist film having openings in respective areas in which the source electrode 213 and the drain electrode 214 are to be formed is provided by a photolithographic technique, and the resist film is then dry etched using chlorine-based gas, thereby forming the openings 211 and 212. Further, a metal film is formed on the resist film by a deposition method using the resist film as a growth mask, and the resist film is removed together with the metal film thereon, thereby forming the source electrode 213 and the drain electrode 214 inside of the respective openings of the resist film. That is, the source electrode 213 and the drain electrode 214 can be formed by a lift-off method. In the formation of the metal film, for example, an Al film is formed after a titanium (Ti) film is formed. After removal of the resist film, heat treatment is performed, for example, at 400° C. to 1000° C. in a nitrogen atmosphere to establish the ohmic characteristics.

Before the formation of the openings 211 and 212, an element separation region may be formed to define an element region in the semiconductor stack structure 206. In the formation of the element separation region, for example, a photoresist pattern is formed on the capping layer 205 to expose an area in which the element separation region is to be formed, and ion implantation, such as argon (Ar) ion implantation, is performed using this photoresist pattern as a mask. The photoresist pattern may be dry etched using a chlorine-based gas as an etch mask. In the element separation region, 2DEG 209 is removed.

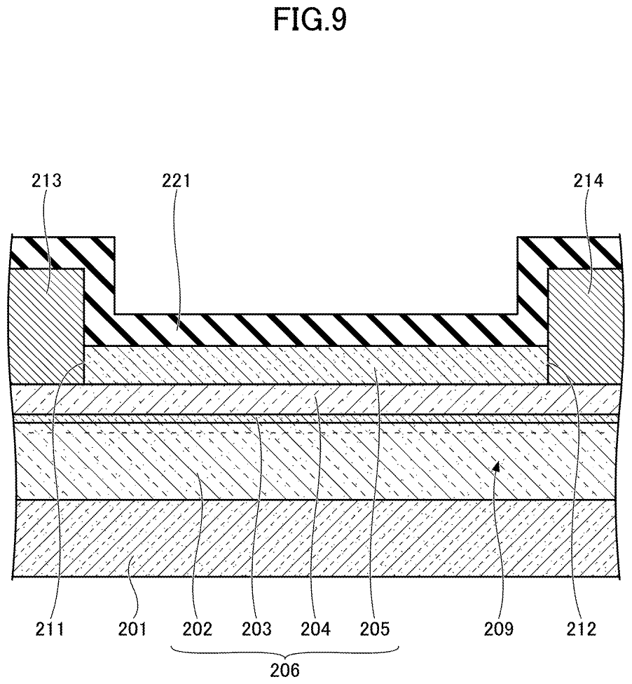

After forming the source electrode 213 and the drain electrode 214, as illustrated in FIG. 9, a first insulating film 221 is formed covering the top surface of the capping layer 205, the side and top surfaces of the source electrode 213, and the side and top surfaces of the drain electrode 214. In forming the first insulating film 221, for example, an aluminum oxide film is formed by a plasma-assisted Atomic Layer Deposition (ALD) method, followed by heat treatment of the aluminum oxide film. The heat treatment is carried out, for example, at a temperature of 600° C. to 1000° C. in a vacuum. The temperature of the heat treatment may be 750° C. The heat treatment time ranges from, for example, 0.5 minutes to 2 minutes. As a result of this heat treatment, oxygen holes are generated in the aluminum oxide film, and the first insulating film 221 is positively charged. That is, the first insulating film 221 after heat treatment has an Al-rich composition. For example, when the composition of aluminum oxide is expressed as Alₓ₁O_{y1} in the first insulating film 221, the value of x1/y1 is greater than 2/3. The formation of the positively charged first insulating film 221 increases the concentration of 2DEG 209 near the top surface of the electron transit layer 202.

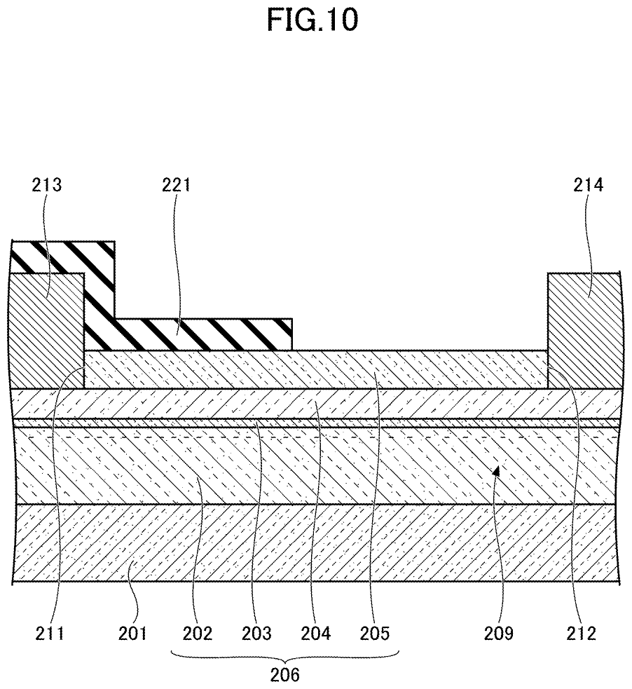

As illustrated in FIG. 10, the first insulating film 221 is then fabricated so as to remain between the gate electrode 230 and the source electrode 213. The first insulating film 221 may be left to cover the side and top surfaces of the source electrode 213. The first insulating film 221 is removed from at least an area where the opening 220 is to be formed and an area between the opening 220 and the drain electrode 214. In the fabrication of the first insulating film 221, a photoresist pattern that exposes an area to be removed from the first insulating film 221, for example, by photolithography is formed on the first insulating film 221, and using this photoresist pattern as an etching mask, wet etching with an alkaline chemical solution, such as tetramethyl ammonium hydroxide (TMAH), is performed. The photoresist pattern is removed after the wet etching. The fabrication of the first insulating film 221 results in a lower concentration of 2DEG 209 near the top surface of the electron transit layer 202 below a portion where the first insulating film 221 is removed.

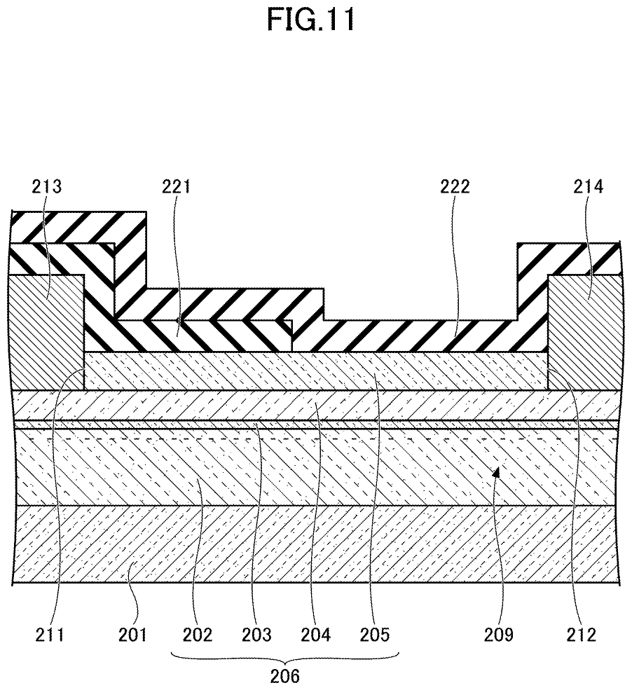

Then, as illustrated in FIG. 11, a second insulating film 222 is formed covering the side and top surfaces of the first insulating film 221, the top surface of the capping layer 205, and the side and top surfaces of the drain electrode 214. In the formation of the second insulating film 222, for example, a film containing a material having a Si—CH₃ bond and a Si—OH bond is applied by a spin-coating method to the side and top surfaces of the first insulating film 221, the top surface of the capping layer 205, and the side and top surfaces of the drain electrode 214. The material having a Si—CH₃ bond and a Si—OH bond can be produced by chemical synthesis. The film is then irradiated with ultraviolet light of a wavelength range of 180 nm to 250 nm so as to promote a cross-linking reaction of Si—O—Si. As the second insulating film 222, for example, a film of methylsilsesquioxane (MSQ) is formed. Heat treatment at a temperature of approximately 200° C. may be performed prior to ultraviolet irradiation. Since the second insulating film 222 is electrically neutral, the formation of the second insulating film 222 hardly changes the concentration of 2DEG 209 near the top surface of the electron transit layer 202.

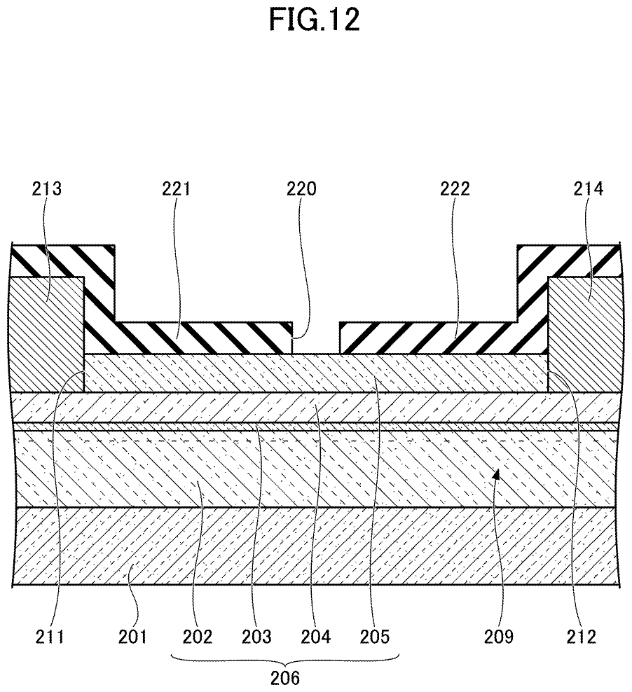

As illustrated in FIG. 12, the second insulating film 222 is then fabricated so as to remain between the gate electrode 230 and the drain electrode 214. The second insulating film 222 may be left to cover the side and top surfaces of the drain electrode 214. The second insulating film 222 is removed from at least an area where the opening 220 is to be provided. In the fabrication of the second insulating film 222, a photoresist pattern that exposes an area to be removed from the second insulating film 222, for example, by photolithography is formed on the second insulating film 222, and using this photoresist pattern as an etching mask, dry etching with a fluorine-based gas is performed. The photoresist pattern is removed after the dry etching. An opening 220 is formed between the end of the first insulating film 221 facing the drain electrode 214 and the end of the second insulating film 222 facing the source electrode 213. Since the second insulating film 222 is electrically neutral, the fabrication of the second insulating film 222 hardly changes in the concentration of 2DEG 209 near the top surface of the electron transit layer 202.

Subsequently, a gate electrode 230 is formed on the first and second insulating films 221 and 222 between the source and drain electrodes 213 and 214 through the opening 220, and is in contact with the capping layer 205 (see FIG. 6). In the formation of the gate electrode 230, for example, a resist film with an opening is provided in an area where the gate electrode 230 is to be formed by a photolithographic technique. Then, a metal film is formed on the resist film by a deposition method using the resist film as a growth mask, and the resist film is removed together with the metal film thereon, thereby forming the gate electrode 230 inside the opening of the resist film. That is, the gate electrode 230 can be formed by the lift-off method. In the formation of the metal film, for example, an Au film is formed after a Ni film is formed.

The semiconductor device 200 according to the second embodiment can be manufactured in this manner.

The second insulating film 222 included in the semiconductor device 200 manufactured by such a method is resistant to defects and is thermally stable. Accordingly, even if various heat treatments are performed after the second insulating film 222 is formed, the second insulating film 222 is hardly affected by the heat history, and thus has a stable property.

With respect to the physical properties of the second insulating film 222 including siloxane polymers, the amount of the Si—CH₃ bond in the second insulating film 222 formed through ultraviolet irradiation at a wavelength of 180 nm to 250 nm is approximately 7×10⁻⁵ nm⁻¹ or less. If the amount of the Si—CH₃ bond is approximately 7×10⁻⁵ nm⁻¹ or less, the density of the second insulating film 222 is 1.15 g/cm³ or more, and the dielectric constant is 2.2 or more. The dielectric constant of 2.2 or more tends to mitigate electric field concentration in the vicinity of the end of the gate electrode 230 on the drain electrode 214 side. The amount of Si—CH₃ bond can be specified as follows using an infrared spectrophotometer (JIR-100 manufactured by Japan Spectroscopy Co., Ltd.). That is, the transmission spectrum is measured in the dual mode (Sample/Background) with the measurement resolution of 4 cm⁻¹, and the result is integrated 60 times. In the transmitted spectrum obtained by the integration, the value obtained by dividing the peak intensity of the Si—CH₃ bond absorbing at around 1276 cm⁻¹ by the film thickness (nm) of the sample is the amount of Si—CH₃ bond.

### Third Embodiment

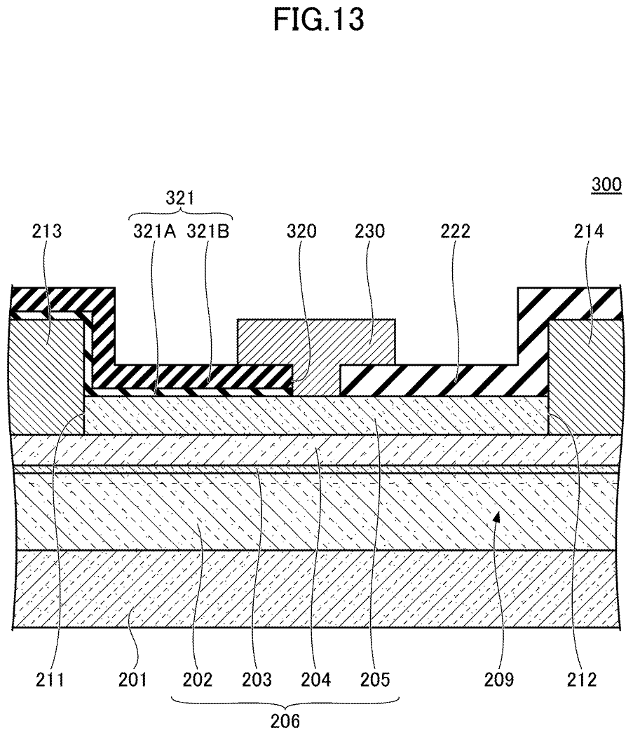

Next, a third embodiment will be described. The third embodiment relates to a semiconductor device having a GaN-based HEMT, which differs from the second embodiment in terms of the configuration of the first insulating film. FIG. 13 is a cross-sectional view illustrating a semiconductor device 300 according to the third embodiment.

As illustrated in FIG. 13, the semiconductor device 300 according to the third embodiment has a first insulating film 321 instead of the first insulating film 221 according to the second embodiment. The first insulating film 321 is in direct contact with the semiconductor stack structure 206. The first insulating film 321 is in contact with the source electrode 213, and extends toward the drain electrode 214. An end of the first insulating film 321 facing the drain electrode 214 is separated in the direction of the drain electrode 214. The end of the first insulating film 321 facing the drain electrode 214 and an end of the second insulating film 222 facing the source electrode 213 are separated from each other, and an opening 320 is provided between these ends of the first insulating film 321 facing the drain electrode 214 and the second insulating film 222 facing the source electrode 213. A gate electrode 230 is disposed on the first and second insulating films 321 and 222 between the source electrode 213 and the drain electrode 214, and the gate electrode 230 is in contact with the capping layer 205 through the opening 320. The first insulating film 321 may cover the side and top surfaces of the source electrode 213.

The first insulating film 321 has a third insulating film 321A and a fourth insulating film 321B on the third insulating film 321A. The third insulating film 321A includes aluminum oxide, and is, for example, an aluminum oxide film. When the composition of aluminum oxide is expressed as Alₓ₁O_{y1}, the value of x1/y1 is greater than 2/3. The thickness of the third insulating film 321A is, for example, approximately 10 nm to 100 nm. The fourth insulating film 321B includes silicon nitride, and is, for example, a silicon nitride film. When the composition of silicon nitride is expressed as Siₓ₂N_{y2}, the value of x2/y2 is greater than 3/4. The thickness of the fourth insulating film 321B may be, for example, 10 nm to 100 nm. The fourth insulating film 321B may be thicker than the third insulating film 321A. The third and fourth insulating films 321A and 321B are positively charged, ionic bonding films, and the first insulating film 321 is also a positively charged, ionic bonding film.

Other configurations are substantially the same as those of the second embodiment.

The same effect as the second embodiment can be obtained by the third embodiment.

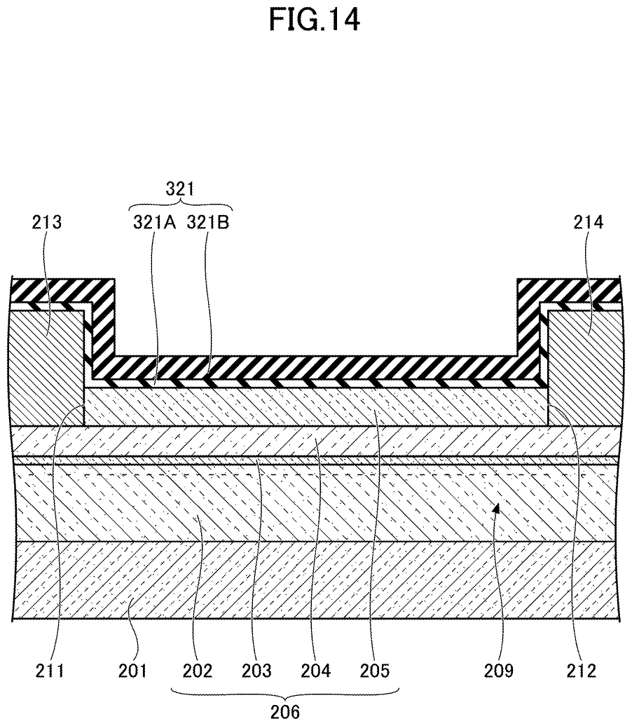

Next, a method for manufacturing the semiconductor device 300 according to the third embodiment will be described. FIGS. 14 to 16 are cross-sectional views illustrating a method for manufacturing the semiconductor device 300 according to the third embodiment.

First, in the same manner as in the second embodiment, a source electrode 213 and a drain electrode 214 are formed, and a subsequent process up to the heat treatment is performed to establish the ohmic characteristics (see FIG. 9). Then, as illustrated in FIG. 14, a first insulating film 321 is formed covering the top surface of the capping layer 205, the side and top surfaces of the source electrode 213, and the side and top surfaces of the drain electrode 214. In forming the first insulating film 321, a stack of the third insulating film 321A and the fourth insulating film 321B on the third insulating film 321A is formed. In forming the third insulating film 321A and the fourth insulating film 321B, for example, an aluminum oxide film is formed by the plasma-assisted Atomic Layer Deposition (ALD) method, a silicon nitride film is formed on the aluminum oxide film by the plasma-enhanced Chemical Vapor Deposition (CVD) method, and then the aluminum oxide film and the silicon nitride film are heat-treated. The heat treatment is carried out, for example, at a temperature of 600° C. to 1000° C. in a vacuum. For example, the temperature of the heat treatment may be 750° C., preferably 850° C. to 1000° C. As a result of this heat treatment, oxygen holes are generated in the aluminum oxide film to obtain the third insulating film 321A which is positively charged, and nitrogen holes are generated in the silicon nitride film to obtain the fourth insulating film 321B which is positively charged. That is, the third insulating film 321A after heat treatment has an Al-rich composition, and the fourth insulating film 321B after heat treatment has a Si-rich composition. For example, when the composition of aluminum oxide is expressed as Alₓ₁O_{y1} in the third insulating film 321A, the value of x1/y1 is greater than 2/3, and when the composition of silicon nitride is expressed as Siₓ₂N_{y2} in the fourth insulating film 321B, the value of x2/y2 is greater than 3/4. The formation of the positively charged first insulating film 321 increases the concentration of 2DEG 209 near the top surface of the electron transit layer 202.

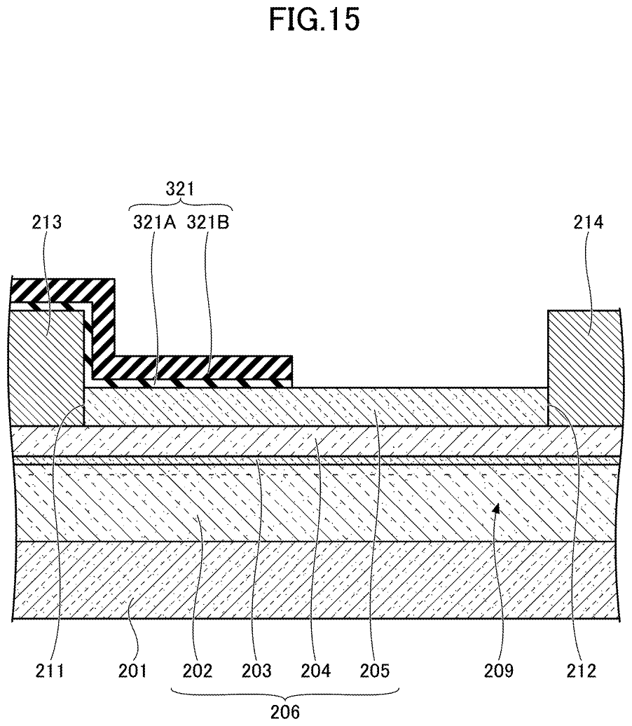

Thereafter, the first insulating film 321 is fabricated, as illustrated in FIG. 15, so as to remain between the gate electrode 230 and the source electrode 213. The first insulating film 321 may be left to cover the side and top surfaces of the source electrode 213. The first insulating film 321 is removed from at least an area where an opening 320 is to be provided and an area between the opening 320 and the drain electrode 214. In the fabrication of the first insulating film 321, a photoresist pattern that exposes an area to be removed from the first insulating film 321, for example, by photolithography is formed on the first insulating film 321. Then, using this photoresist pattern as an etching mask, dry etching of the fourth insulating film 321B using the fluorine-based gas and wet etching of the third insulating film 321A using an alkaline chemical solution such as tetramethylammonium hydroxide (TMAH) are performed. The photoresist pattern is removed after fabrication of the first insulating film 321. The fabrication of the first insulating film 321 results in a lower concentration of 2DEG 209 near the top surface of the electron transit layer 202 below the removed portion of the first insulating film 321.

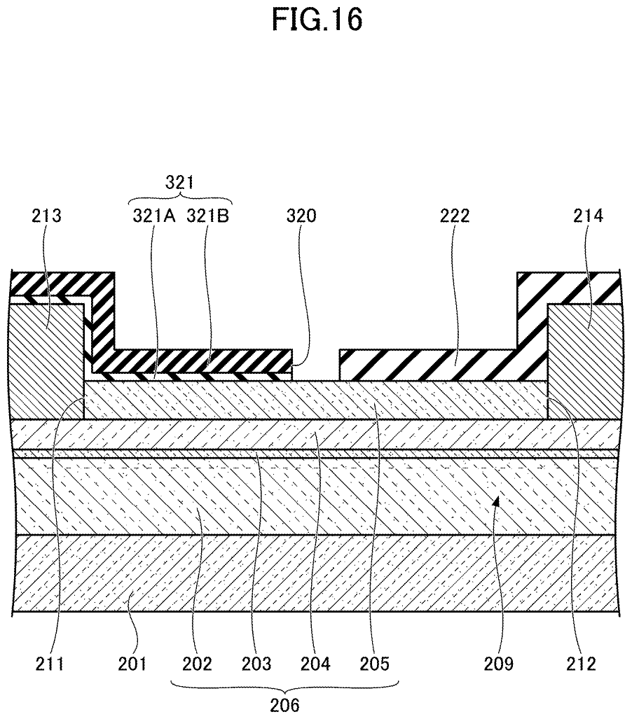

Subsequently, as illustrated in FIG. 16, the second insulating film 222 is formed and fabricated in the same manner as in the second embodiment. An opening 320 is formed between the end of the first insulating film 321 facing the drain electrode 214 and the end of the second insulating film 222 facing the source electrode 213. A gate electrode 230 is then formed through the opening 320 to come in contact with the capping layer 205 (see FIG. 13).

In this manner, the semiconductor device 300 according to the third embodiment can be manufactured.

When forming the first insulating film 321, an aluminum oxide film may be formed and heat treated, and then a silicon nitride film may be formed and heat treated. For example, the aluminum oxide film may be heat treated at 750° C., and the silicon nitride film may be heat treated at 850° C.

### Fourth Embodiment

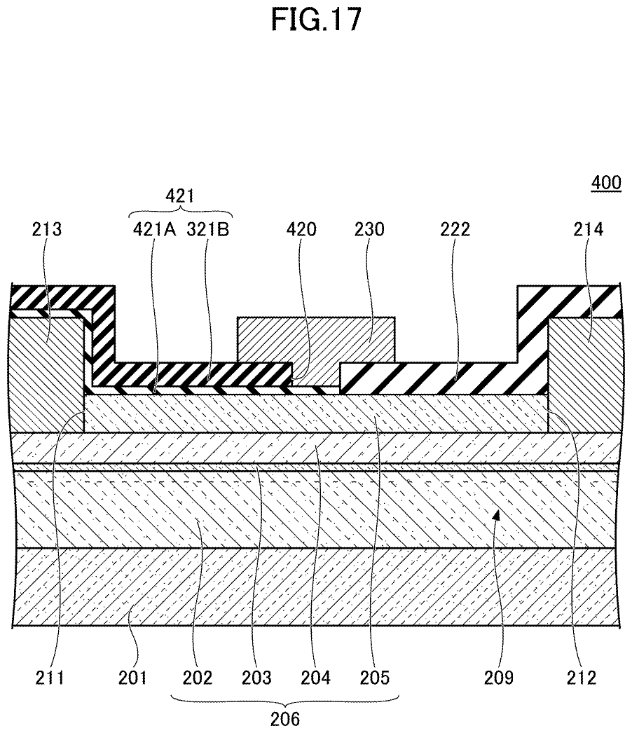

Next, a fourth embodiment will be described. The fourth embodiment relates to a semiconductor device having a GaN-based HEMT, which differs from the third embodiment in terms of the configuration of the first insulating film. FIG. 17 is a cross-sectional view illustrating a semiconductor device 400 according to the fourth embodiment.

The semiconductor device 400 according to the fourth embodiment has a first insulating film 421 instead of the first insulating film 321 according to the third embodiment, as illustrated in FIG. 17. The first insulating film 421 is in direct contact with the semiconductor stack structure 206. The first insulating film 421 is in contact with the source electrode 213 and extends toward the drain electrode 214. An end of the first insulating film 421 facing the drain electrode 214 is separated from the drain electrode 214.

The first insulating film 421 has a third insulating film 421A and a fourth insulating film 321B on the third insulating film 421A. The third insulating film 421A includes aluminum oxide, and is, for example, an aluminum oxide film. When the composition of aluminum oxide is expressed as Alₓ₁O_{y1}, the value of x1/y1 is greater than 2/3. The thickness of the third insulating film 421A is, for example, approximately 10 nm to 100 nm. The fourth insulating film 321B may be thicker than the third insulating film 421A. The third and fourth insulating films 421A and 321B are positively charged, ionic bonding films, and the first insulating film 421 is also a positively charged, ionic bonding film.

Unlike the third insulating film 321A in the third embodiment, an end of the third insulating film 421A facing the drain electrode 214 is in contact with an end of the second insulating film 222 facing the source electrode 213. In contrast to this, an end of the fourth insulating film 321B facing the drain electrode 214 and an end of the second insulating film 222 facing the source electrode 213 are separated from each other, and an opening 420 is provided between these ends of the fourth insulating film 321B facing the drain electrode 214 and the second insulating film 222 facing the source electrode 213. A gate electrode 230 is provided on the first and second insulating films 421 and 222 between the source electrode 213 and the drain electrode 214, and the gate electrode 230 is in contact with a top surface of the third insulating film 421A through the opening 420. The first insulating film 421 may cover the side and top surfaces of the source electrode 213.

Other configurations are the same as in the third embodiment.

The fourth embodiment can obtain the same effect as the third embodiment.

As described above, a gate structure may be of the Schottky type or of the MIS (metal-insulator-semiconductor) type.

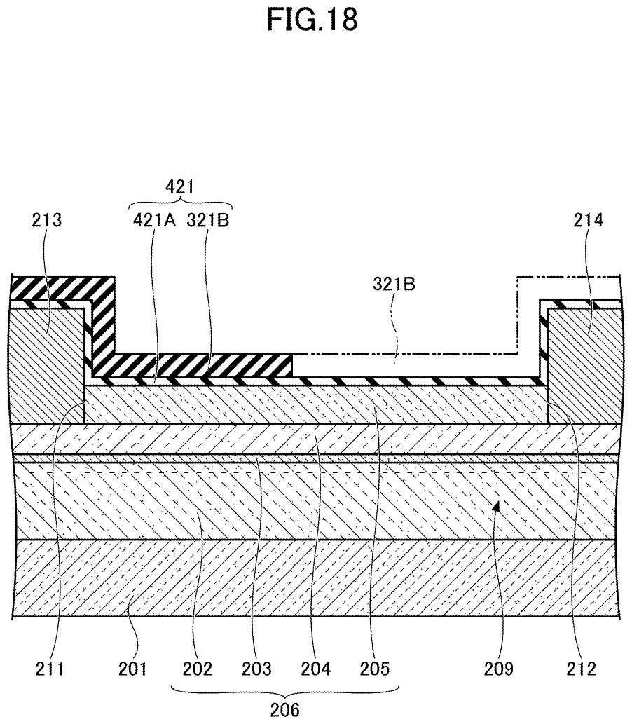

Next, a method for manufacturing the semiconductor device 400 according to the fourth embodiment will be described. FIGS. 18 to 20 are cross-sectional views illustrating a method for manufacturing the semiconductor device 400 according to the fourth embodiment.

First, in the same manner as in the second embodiment, a source electrode 213 and a drain electrode 214 are formed, and a subsequent process up to the heat treatment is performed to establish the ohmic characteristics (see FIG. 9). Then, as illustrated in FIG. 18, a first insulating film 421 is formed covering the top surface of the capping layer 205, the side and top surfaces of the source electrode 213, and the side and top surfaces of the drain electrode 214. In forming the first insulating film 421, a stack of a third insulating film 421A and a fourth insulating film 321B on the third insulating film 421A is formed. The third and fourth insulating films 421A and 321B are formed by forming an aluminum oxide film, forming a silicon nitride film, and heat treating the aluminum oxide film and the silicon nitride film in the same manner as the third and fourth insulating films 321A and 321B in the third embodiment.

The fourth insulating film 321B is then fabricated so as to remain between the gate electrode 230 and the source electrode 213, as illustrated in FIG. 18. The fourth insulating film 321B may be left to cover the side and top surfaces of the source electrode 213. The fourth insulating film 321B is removed from at least an area where an opening 420 is to be provided and an area between the opening 420 and the drain electrode 214. In the fabrication of the fourth insulating film 321B, a photoresist pattern that exposes an area to be removed from the fourth insulating film 321B, for example, by photolithography is formed on the fourth insulating film 321B, and using this photoresist pattern as an etching mask, dry etching with a fluorine-based gas is performed. The photoresist pattern is removed after dry etching.

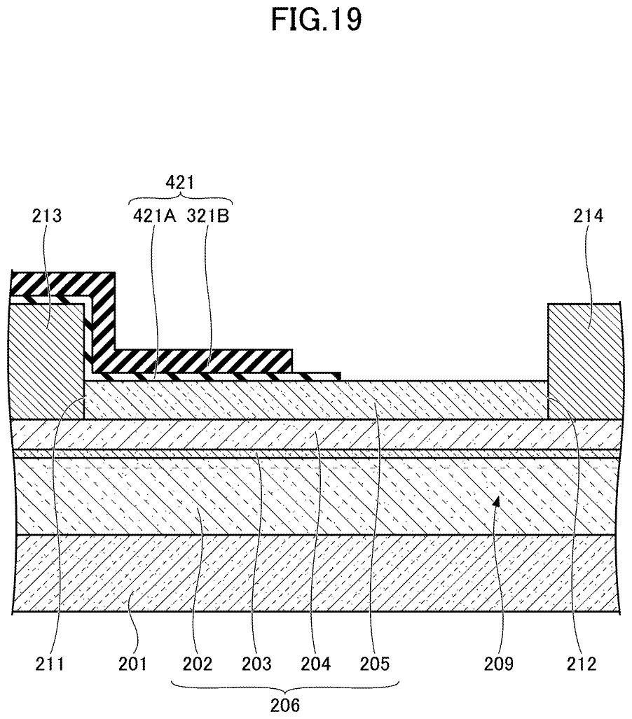

The third insulating film 421A is then fabricated so as to remain between the gate electrode 230 and the source electrode 213, and below the opening 420, as illustrated in FIG. 19. The third insulating film 421A may be left to cover the side and top surfaces of the source electrode 213. The third insulating film 421A is removed from at least an area between the opening 420 and the drain electrode 214, and remains in the area where the opening 420 is to be provided. In the fabrication of the third insulating film 421A, a photoresist pattern that exposes an area to be removed from the third insulating film 421A, for example, by photolithography is formed on the fourth insulating film 321B and the third insulating film 421A, and using this photoresist pattern as an etching mask, wet etching using an alkaline chemical solution, such as tetramethylammonium hydroxide (TMAH), is performed. The photoresist pattern is removed after the wet etching.

The fabrication of the first insulating film 421 results in a lower concentration of 2DEG 209 near the top surface of the electron transit layer 202 below the area where the first insulating film 421 is removed.

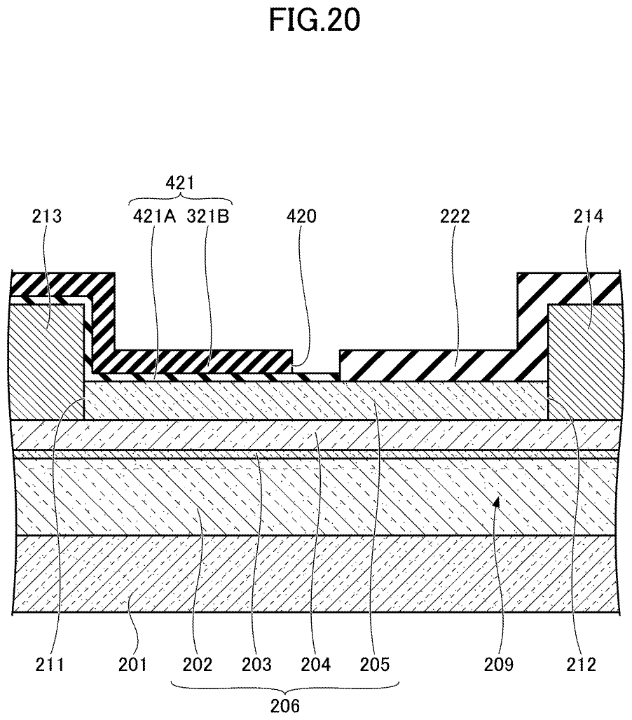

Subsequently, as illustrated in FIG. 20, the second insulating film 222 is formed and fabricated in the same manner as in the second embodiment. An opening 420 is formed between an end of the fourth insulating film 321B facing the drain electrode 214 and an end of the second insulating film 222 facing the source electrode 213. A gate electrode 230 is then formed to be in contact with the top surface of the third insulating film 421A through the opening 420 (see FIG. 17).

The semiconductor device 400 according to the fourth embodiment can be manufactured in this manner.

### Fifth Embodiment

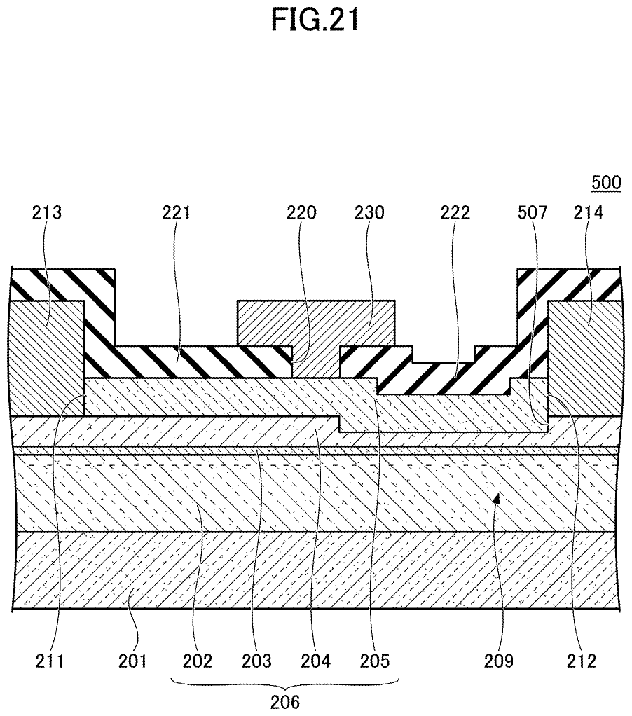

Next, a fifth embodiment will be described. The fifth embodiment relates to a semiconductor device having a GaN-based HEMT, which differs from the second embodiment in terms of the configuration of the electron supply layer. FIG. 21 is a cross-sectional view illustrating a semiconductor device 500 according to the fifth embodiment.

As illustrated in FIG. 21, in the semiconductor device 500 according to the fifth embodiment, a recess 507 is formed on a top surface of the electron supply layer 204 in an area between an end of the opening 220 oriented toward an opening 212 and an end of the opening 212 oriented toward to the opening 220 in a plan view. Other configurations are substantially the same as those of the second embodiment.

In the fifth embodiment, since the recess 507 is formed on the top surface of the electron supply layer 204, the thickness of electron supply layer 204 is smaller in an area between the gate electrode 230 and the drain electrode 214 in plan view than an area between the gate electrode 230 and the source electrode 213 in plan view. Accordingly, the concentration of 2DEG between the gate electrode 230 and the drain electrode 214 is lower, and the drain breakdown voltage can thus be further improved.

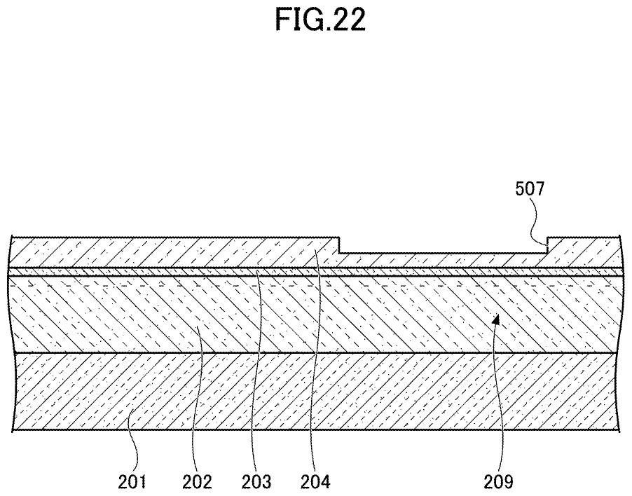

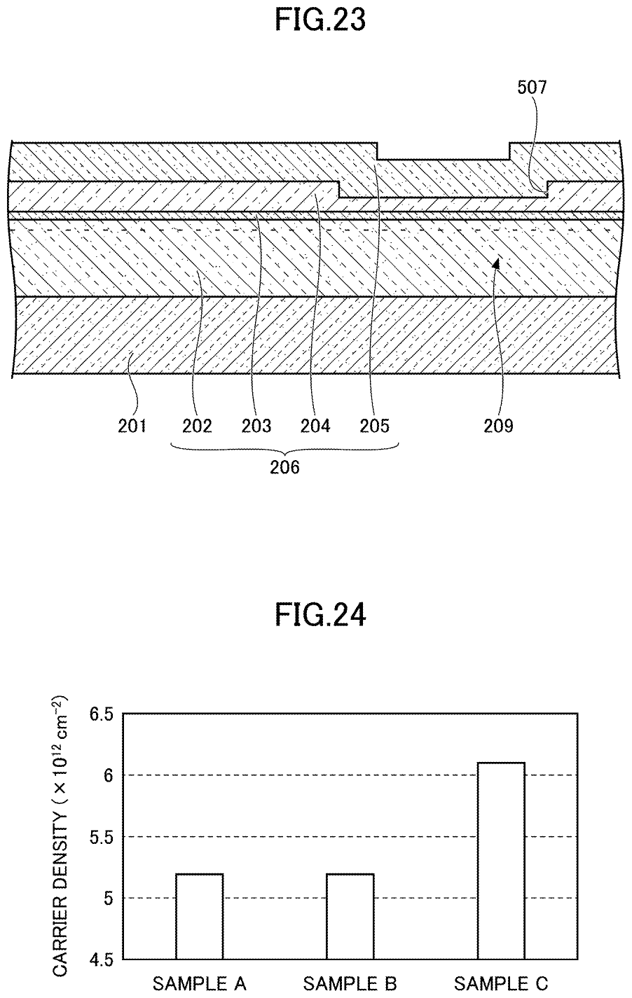

Next, a method for manufacturing the semiconductor device 500 according to the fifth embodiment will be described. FIGS. 22 to 23 are cross-sectional views illustrating a method for manufacturing the semiconductor device 500 according to the fifth embodiment.

First, the process up to the formation of the electron supply layer 204 is performed in the same manner as in the second embodiment (see FIG. 7). A recess 507 is then formed on the top surface of the electron supply layer 204, as illustrated in FIG. 22. In forming the recess 507, a photoresist pattern is formed on the electron supply layer 204 to expose an area to form the recess 507 by, for example, photolithography, and dry etching with chlorine-based gas is performed using this photoresist pattern as an etch mask. The photoresist pattern is removed after dry etching. The formation of the recess 507 results in a lower concentration of 2DEG 209 near the top surface of the electron transit layer 202 below a portion where the recess 507 is formed.

Subsequently, as illustrated in FIG. 23, a capping layer 205 is formed on the electron supply layer 204. This results in a semiconductor stack structure 206. Thereafter, the process of forming forming the openings 211 and 212 and beyond are performed in the manner similar to the second embodiment.

The semiconductor device 500 according to the fifth embodiment can thus be manufactured in this manner.

Note that the electron supply layer 204 on which the recess 507 is formed may be used in the third or fourth embodiment.

The following describes an experiment performed according to the embodiments of the present application. In this experiment, three samples A, B, and C were prepared. The sample A is a sample that includes a substrate 201 and a semiconductor stack structure 206 in the second embodiment. The sample B is a sample obtained by forming a siloxane polymer film on the semiconductor stack structure 206 of the sample A. The sample C is a sample obtained by forming an aluminum oxide film on the semiconductor stack structure 206 of the sample A. In this experiment, the sample A, the sample B, and the sample C were subjected to heat treatment at 350° C. (corresponding to the heat history of the interconnect process) for 1 hour, and then the carrier density was evaluated. This result is illustrated in FIG. 24. FIG. 24 is a diagram illustrating the measurement results of the carrier density.

As illustrated in FIG. 24, there is no significant difference between the sample B and the sample A, but the carrier density in the sample C was approximately 15% higher than that in the sample A. This indicates that the sample A is suitable for improving the concentration of 2DEG, and that the sample B is hardly affected by the heat history and remains electrically neutral.

The first insulating film 221 may include silicon nitride, silicon oxynitride, aluminum oxide, or aluminum oxynitride, or any combination thereof. For example, the first insulating film 221 may include a first element that becomes a cation and a second element that becomes an anion, and the difference between electronegativity of the second element and electronegativity of the first element may be greater than 1.7. When the first insulating film 221 includes silicon nitride, the temperature of the heat treatment to generate the nitrogen holes is preferably 750° C. or more, more preferably 800° C. or more, and still more preferably 850° C. or more. The second insulating film 222 may be a silicon oxide or hydrocarbon film.

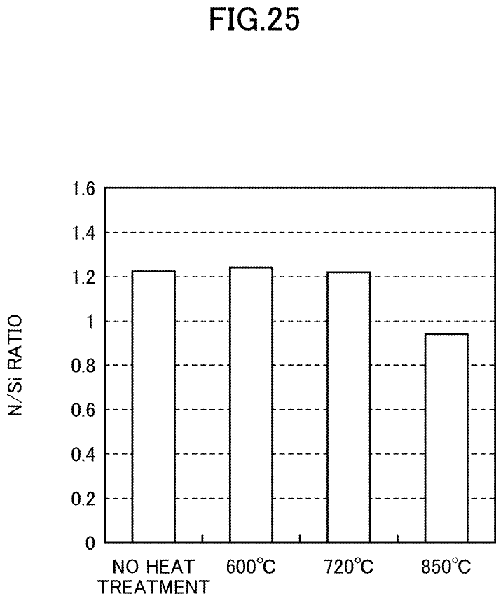

FIG. 25 illustrates a relationship between the heat treatment temperature and the N/Si ratio of the silicon nitride film. FIG. 25 illustrates the N/Si ratio after heat treatment of the silicon nitride film formed by the plasma-enhanced CVD method at various temperatures. As illustrated in FIG. 25, there is no significant difference between heat treatment at 600° C. and heat treatment at 720° C., but the N/Si ratio is greatly reduced by heat treatment at 850° C. This indicates that silicon nitride easily becomes Si-rich by heat treatment at 850° C.

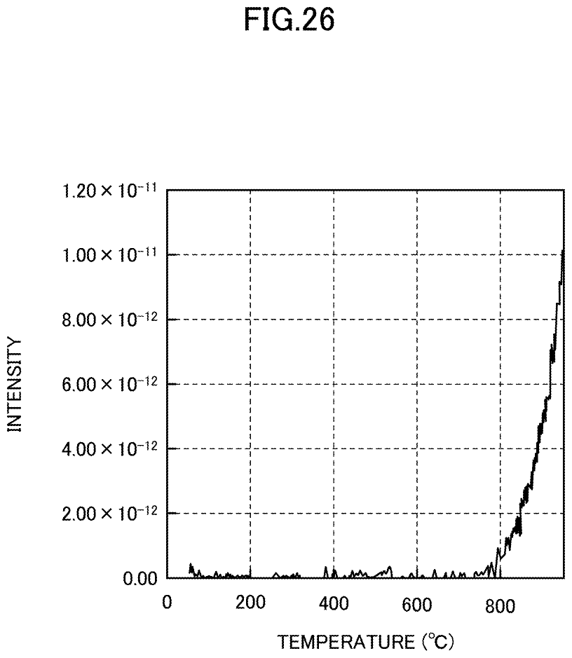

FIG. 26 illustrates a thermal desorption profile for N₂. FIG. 26 illustrates a change in the amount of N₂ desorbed from the silicon nitride film when the temperature of the silicon nitride film formed by the plasma-enhanced CVD method is raised at a rate of 0.2° C./sec. As illustrated in FIG. 26, N₂ starts to desorb at a temperature of approximately 750° C., and N₂ desorption becomes pronounced at a temperature of approximately 800° C.

Note that compositions of the compound semiconductor layers included in the semiconductor stack structure are not limited to those described in the above-described embodiments. For example, nitride semiconductors such as InAlN, InGaAlN, and the like may be used. Compound semiconductors such as InP may also be used.

In addition, the sequence of steps in the manufacturing method in the present disclosure is not limited to those described in the above embodiments. For example, the insulating films may be formed prior to the source and drain electrodes.

### Sixth Embodiment

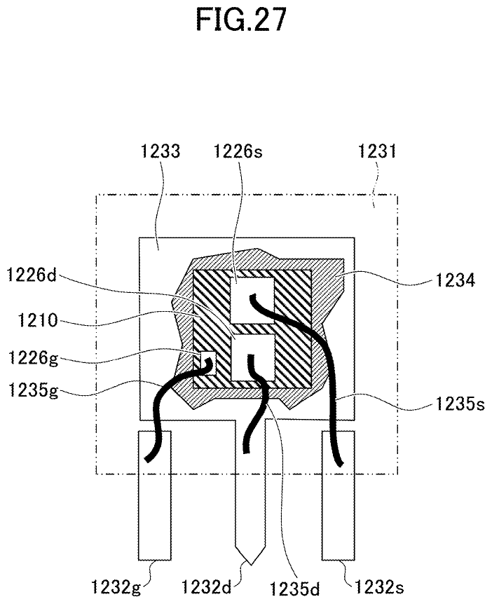

Next, a sixth embodiment will be described. The sixth embodiment relates to a discrete package of a HEMT. FIG. 27 is a diagram illustrating a discrete package according to a sixth embodiment.

In the sixth embodiment, as illustrated in FIG. 27, a back surface of a semiconductor device 1210 having the same structure as any of the first to fifth embodiments is secured to a land (die pad) 1233 using a die attach agent 1234, such as solder. One end of a wire 1235d, such as an Al wire, is connected to a drain pad 1226d to which the drain electrode 114 or 214 is connected, and the other end of the wire 1235d is connected to a drain lead 1232d integral with the land 1233. One end of a wire 1235s, such as Al wire, is connected to a source pad 1226s to which the source electrode 113 or 213 is connected, and the other end of the wire 1235s is connected to a source lead 1232s independent of the land 1233. One end of a wire 1235g, such as Al wire, is connected to a gate pad 1226g to which the gate electrode 130 or 230 is connected, and the other end of the wire 1235g is connected to a gate lead 1232g independent of the land 1233. The land 1233 and the semiconductor device 1210 are then packaged with a mold resin 1231 such that a portion of the gate lead 1232g, a portion of the drain lead 1232d, and a portion of the source lead 1232s protrude.

Such a discrete package may be manufactured, for example, as follows. First, the semiconductor device 1210 is secured to the land 1233 of a lead frame using a die attach agent 1234, such as solder. Subsequently, with wire bonding using the wires 1235g, 1235d and 1235s, the gate pad 1226g is connected to the gate lead 1232g of the lead frame, the drain pad 1226d is connected to the drain lead 1232d of the lead frame, and the source pad 1226s is connected to the source lead 1232s of the lead frame. Thereafter, sealing is performed using a mold resin 1231 by transfer mold method. The lead frame is then disconnected.

### Seventh Embodiment

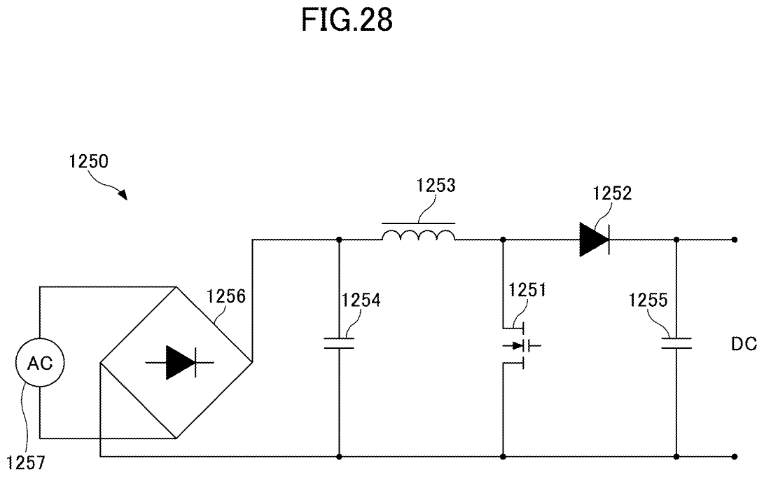

Next, a seventh embodiment will be described. The seventh embodiment relates to a PFC (Power Factor Correction) circuit having a HEMT. FIG. 28 is a line diagram illustrating a PFC circuit 1250 according to the seventh embodiment.

The PFC circuit 1250 is provided with a switch element (transistor) 1251, a diode 1252, a choke coil 1253, capacitors 1254 and 1255, a diode bridge 1256, and an alternating current power supply (AC) 1257. The drain electrode of the switch element 1251 is connected to an anode terminal of the diode 1252 and one terminal of the choke coil 1253. The source electrode of the switch element 1251 is connected to one terminal of the capacitor 1254 and one terminal of capacitor 1255. The other terminal of the capacitor 1254 is connected to the other terminal of the choke coil 1253. The other terminal of the capacitor 1255 is connected to a cathode terminal of the diode 1252. Further, a gate driver is connected to a gate electrode of the switch element 1251. An AC 1257 is connected between the terminals of the capacitor 1254 via the diode bridge 1256. A direct current (DC) is connected between the terminals of the capacitor 1255. According to the seventh embodiment, a compound semiconductor device having the same structure as any of the first to fifth embodiments is used for the switch element 1251.

In manufacturing the PFC circuit 1250, for example, a solder or the like is used to connect the switch element 1251 to the diode 1252, the choke coil 1253, or the like.

### Eighth Embodiment

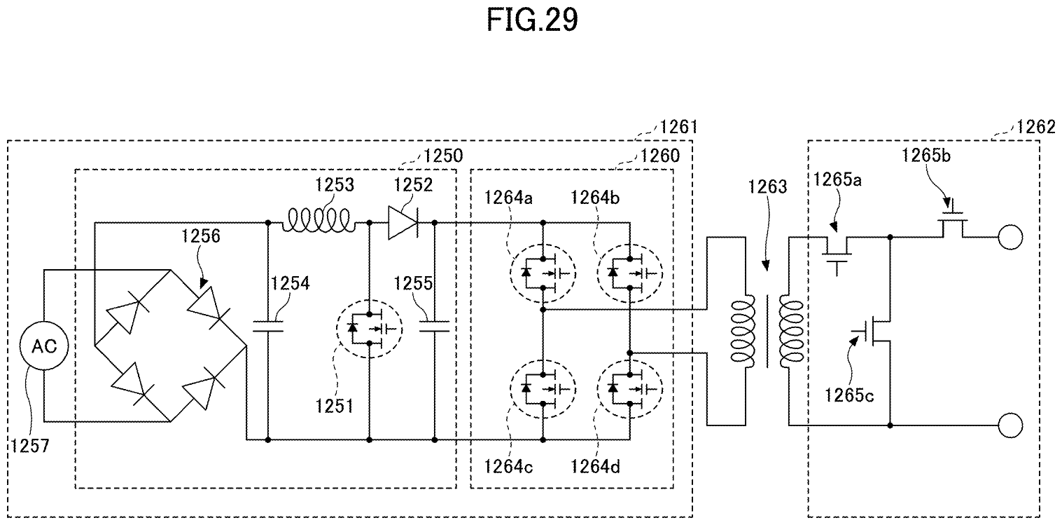

Next, an eighth embodiment will be described. An eighth embodiment relates to a power supply device having a HEMT, which is suitable for server power supply. FIG. 29 is a line diagram illustrating a power supply device according to the eighth embodiment.

The power supply is provided with a high voltage primary circuit 1261, a low voltage secondary circuit 1262, and a transformer 1263 disposed between the primary circuit 1261 and the secondary circuit 1262.

The primary circuit 1261 includes the PFC circuit 1250 according to the seventh embodiment, and an inverter circuit such as a full bridge inverter circuit 1260. The full bridge inverter circuit 1260 is connected between terminals of the capacitor 1255 of the PFC circuit 1250. The full bridge inverter circuit 1260 is provided with a plurality (four in this example) of switch elements 1264a, 1264b, 1264c, and 1264d.

The secondary circuit 1262 includes a plurality (three in this example) of switch elements 1265a, 1265b, and 1265c.

According to the eighth embodiment, a compound semiconductor device having the same structure as any of the first to fifth embodiments is used for the switch element 1251 of the PFC circuit 1250 that forms the primary circuit 1261, and is also used for the switch elements 1264a, 1264b, 1264c, and 1264d of the full bridge inverter circuit 1260. In contrast to this, related art MIS-type FETs (field effect transistors) using silicon are used for the switch elements 1265a, 1265b, and 1265c of the secondary circuit 1262.

### Ninth Embodiment

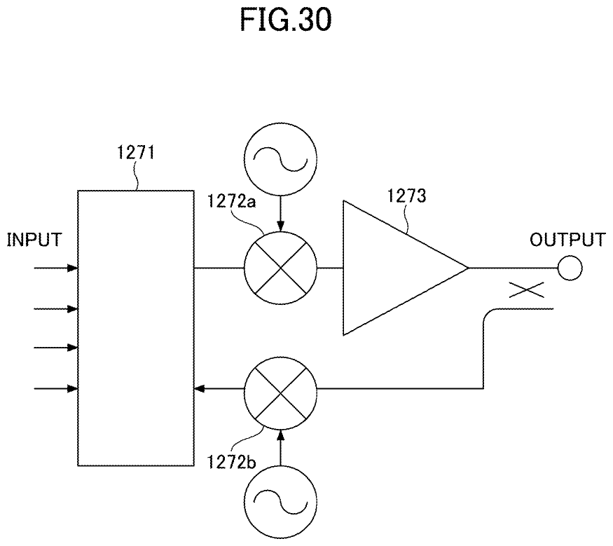

Next, a ninth embodiment will be described. The ninth embodiment relates to an amplifier having a HEMT. FIG. 30 is a line diagram illustrating an amplifier according to the ninth embodiment.

The amplifier is provided with a digital predistortion circuit 1271, mixers 1272a and 1272b, and a power amplifier 1273.

The digital predistortion circuit 1271 compensates for nonlinear strain of an input signal. The mixer 1272a mixes the nonlinear strain compensated input signal and an alternating current (AC) signal. The power amplifier 1273 includes a compound semiconductor device having a structure similar to any of the first to fifth embodiments, and amplifies the input signal mixed with the AC signal. Note that in this embodiment, for example, by switching the switching elements, an output signal may be mixed with an alternating current signal by the mixer 1272b, and the mixed signals may be transmitted to the digital predistortion circuit 1271. The amplifier can be used as a high-frequency amplifier, or a high-power amplifier. High-frequency amplifiers can be used, for example, in transmitting and receiving devices for cellular base stations, radar devices, and microwave generators.

Although the preferred embodiments have been described in detail above, various alterations and substitutions can be made to the above-described embodiments without departing from the scope of the claims.

### Effect of the Invention

According to the present disclosure, the drain breakdown voltage can be stably improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A semiconductor device comprising:
a semiconductor stack structure having an electron transit layer and an electron supply layer, the electron transit layer and the electron supply layer being compound semiconductors;
a gate electrode, a source electrode, and a drain electrode, the gate electrode, the source electrode, and the drain electrode being disposed above the electron supply layer;
a first insulating film disposed on the semiconductor stack structure between the gate electrode and the source electrode, the first insulating film being positively charged and in direct contact with the semiconductor stack structure; and
a second insulating film disposed on the semiconductor stack structure between the gate electrode and the drain electrode, the second insulating film being covalent and in direct contact with the semiconductor stack structure.

2. The semiconductor device as claimed in claim 1, wherein the second insulating film includes a siloxane polymer.

3. The semiconductor device as claimed in claim 2, wherein density of the second insulating film is 1.1 g/cm³ or more.

4. The semiconductor device as claimed in claim 2, wherein a dielectric constant of the second insulating film is 2.2 or more.

5. The semiconductor device as claimed in claim 1, wherein the first insulating film is an ionic bonding film.

6. The semiconductor device as claimed in claim 1, wherein the first insulating film includes silicon nitride, silicon oxynitride, aluminum oxide, or aluminum oxynitride, or any combination thereof.

7. The semiconductor device as claimed in claim 6, wherein the first insulating film includes aluminum oxide, and
wherein when a composition of the aluminum oxide is expressed as Alₓ₁O_{y1}, a value of x1/y1 is greater than 2/3.

8. The semiconductor device as claimed in claim 6, wherein the first insulating film includes silicon nitride, and
wherein when a composition of the silicon nitride is expressed as Siₓ₂N_{y2}, a value of x2/y2 is greater than 3/4.

9. The semiconductor device as claimed in claim 1, wherein the first insulating film includes a first element that becomes a cation, and a second element that becomes an anion, and
wherein a difference between electronegativity of the second element and electronegativity of the first element is greater than 1.7.

10. A method for manufacturing a semiconductor device, the method comprising:
forming a semiconductor stack structure, the semiconductor stack structure including an electron transit layer and an electron supply layer, the electron transit layer and the electron supply layer being compound semiconductors;
forming a source electrode and a drain electrode, the source electrode and the drain electrode being formed above the electron supply layer;
forming a first insulating film on the semiconductor stack structure between the source electrode and the drain electrode, the first insulating film being positively charged and directly in contact with the semiconductor stack structure and being separated from the drain electrode;
forming a second insulating film on the semiconductor stack structure between the source electrode and the drain electrode, the second insulating film being covalent and directly in contact with the semiconductor stack structure and being separated from the source electrode and the first insulating film; and
forming a gate electrode above the electron supply layer between the first insulating film and the second insulating film.

11. The method as claimed in claim 10, wherein the forming of the second insulating film includes
forming a film including a material having a Si—CH₃ bond and a Si—OH bond, and
irradiating the film with ultraviolet light of a wavelength range of 180 nm to 250 nm.
